(19) United States
(12) Patent Application Publication
(10) Pub. No.: US 2025/0031437 A1
(43) Pub. Date: Jan. 23, 2025

(54) SEMICONDUCTOR DEVICE AND MANUFACTURING METHOD THEREOF

(71) Applicant: INNOSCIENCE (SUZHOU) SEMICONDUCTOR CO., LTD., Jiangsu (CN)

(72) Inventors: Xiaoming LIU, Guangdong (CN); Rong YANG, Guangdong (CN)

(73) Assignee: INNOSCIENCE (SUZHOU) SEMICONDUCTOR CO., LTD., Jiangsu (CN)

(21) Appl. No.: 18/711,110

(22) PCT Filed: Jul. 19, 2022
(86) PCT No.: PCT/CN2022/106424

§ 371 Date: May 17, 2024

(51) Int. Cl. H01L 27/07; H01L 21/8252; H01L 23/528; H01L 27/02; H01L 29/20; H01L 29/778

(52) U.S. Cl. CPC H01L 27/0727; H01L 21/8252; H01L 23/528; H01L 27/0288; H01L 29/2003; H01L 29/7786

(57) ABSTRACT

The present disclosure provides a semiconductor device and a fabrication method thereof. The semiconductor device includes: a substrate (120); a first nitride semiconductor layer (130) on the substrate (120); a second nitride semiconductor layer (140) on the first nitride semiconductor layer (130) and having a band gap greater than a band gap of the first semiconductor layer (130); a transistor (14) on the second nitride semiconductor layer (140); and a protection circuit (40) on the second nitride semiconductor layer (140), wherein the protection circuit (40) is configured to dispel electrons from a gate node of the transistor (14) when a voltage on the gate node exceeds a first threshold voltage.

### BACKGROUND

### 1. Technical Field

The present disclosure relates to a semiconductor device and a manufacturing method thereof, and more particularly to a semiconductor device including a clamping element and a manufacturing method thereof.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET) and the like. It is important to increase the reliability of the semiconductor components.

### SUMMARY

In some embodiments of the present disclosure, a semiconductor device is provided. The semiconductor device includes a substrate, a first nitride semiconductor layer, a second nitride semiconductor layer, a switching element, a capacitor and a clamping element. The first nitride semiconductor layer is formed on the substrate. The second nitride semiconductor layer is formed on the first nitride semiconductor layer. The switching element is formed on the second nitride semiconductor layer. The capacitor is adjacent to the switching element. The clamping element is formed on the second nitride semiconductor layer, and the clamping element is adjacent to the capacitor and electrically connected to the switching element.

In some embodiments of the present disclosure, a method for manufacturing a semiconductor device is provided. The method includes forming a first nitride semiconductor layer on a substrate, forming a second nitride semiconductor layer on the first nitride semiconductor layer, forming a switching element on the second nitride semiconductor layer, forming a capacitor adjacent to the switching element, and forming a clamping element on the second nitride semiconductor layer. The clamping element is adjacent to the capacitor and electrically connected to the switching element.

In some embodiments of the present disclosure, a semiconductor device is provided. The semiconductor device includes a substrate, a first nitride semiconductor layer, a second nitride semiconductor layer, a transistor and a protection circuit. The first nitride semiconductor layer is formed on the substrate. The second nitride semiconductor layer is formed on the first nitride semiconductor layer. The second nitride semiconductor layer has a band gap greater than a band gap of the first semiconductor layer. The transistor is formed on the second nitride semiconductor layer. The protection circuit is formed on the second nitride semiconductor layer. The protection circuit is configured to dispel electrons from a gate node of the transistor when a voltage on the gate node exceeds a first threshold voltage.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may have arbitrarily increased or reduced for clarity of discussion.

FIG. 1 is a top view of a layout of a semiconductor device according to some embodiments of the present disclosure.

FIG. 2 is a cross-sectional view of a semiconductor device according to some embodiments of the present disclosure.

FIG. 3 is another cross-sectional view of a semiconductor device according to some embodiments of the present disclosure.

FIG. 4 is a schematic circuit diagram of a semiconductor device according to some embodiments of the present disclosure.

FIG. 5A is a schematic illustrating the voltage of the node Vin of a semiconductor device according to some embodiments of the present disclosure.

FIG. 5B is a schematic illustrating the voltage of the node VG of a semiconductor device according to some embodiments of the present disclosure.

FIG. 6 is a flowchart of operations in the manufacture of a semiconductor device according to some embodiments of the present disclosure.

### DETAILED DESCRIPTION

The following disclosure provides many different embodiments, or examples, for implementing different features of the provided subject matter. Specific examples of components and arrangements are described as follow. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may have formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail as follows. It should be appreciated, however, that the present disclosure provides many applicable concepts that may be embodied in a wide variety of specific contexts. The specific embodiments discussed are merely illustrative and do not limit the scope of the disclosure.

A direct band gap material, such as a group III-V compound, may include but is not limited to, for example, gallium arsenide (GaAs), indium phosphide (InP), gallium nitride (GaN), Indium gallium arsenide (InGaAs), Indium aluminum arsenide (InAlAs), and the like.

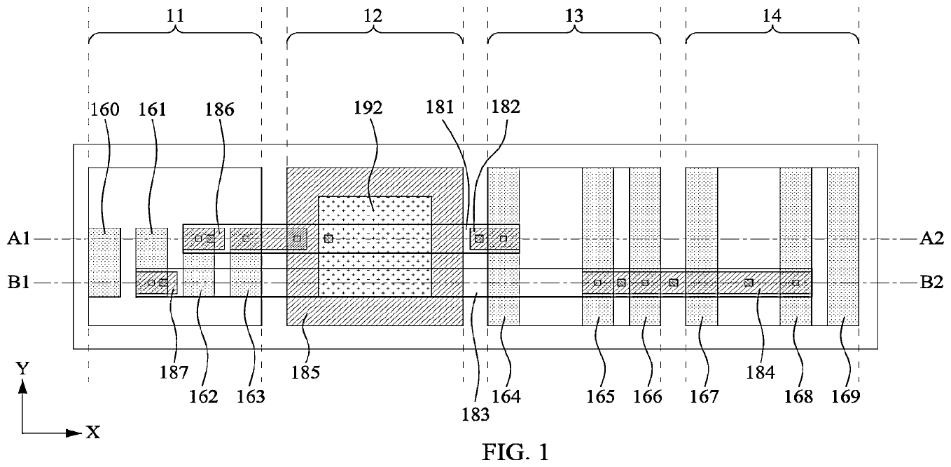

FIG. 1 is a top view of a layout of a semiconductor device 1 according to some embodiments of the present disclosure.

As shown in FIG. 1, the semiconductor device 1 may include a clamping element 11, a capacitor 12, a switching element 13, and a transistor 14. The clamping element 11 may be adjacent to the capacitor 12. The capacitor 12 may be adjacent to the switching element 13. The switching element 13 may be adjacent to the transistor 14. The capacitor 12 may be arranged between the clamping element 11 and the switching element 13. The switching element 13 may be arranged between the capacitor 12 and the transistor 14. In some embodiments, the clamping element 11, the capacitor 12, the switching element 13 and the transistor 14 may be electrically coupled. The clamping element 11, the capacitor 12, the switching element 13 and the transistor 14 may be in electrical contact.

The clamping element 11 may include the conductive structures 160, 161, 162, and 163, the metal layers 181, 186, and 187, and contacts and vias. The layout of the conductive structures 160, 161, 162, and 163 may be in a shape of a rectangle. For the conductive structures 160, 161, 162, and 163, the rectangle can have a short side along an X direction and a long side along a Y direction. The layout of the metal layers 181, 186, and 187 may be in a shape of a rectangle. For the layout of the metal layers 181, 186, and 187, the rectangle can have a short side along the Y direction and a long side along the X direction. The metal layers 181, 186, and 187 can electrically connect to the conductive structures 160, 161, 162, and 163 through the contacts or the vias. Note that some elements may be omitted from the layout shown in FIG. 1 for simplicity and clarity.

The capacitor 12 may include metal layers 181 and 185, the insulating layer, and the conductive layer 192. The layout of the metal layer 185 may be square. The layout of the metal layer 185 may be rectangular. The layout of the conductive layer 192 may be square. The layout of the conductive layer 192 may be rectangular. An area of the conductive layer 192 may be smaller than an area of the metal layer 185. Note that some elements may be omitted from the layout shown in FIG. 1 for simplicity and clarity.

The switching element 13 may include the conductive structures 164, 165, and 166, the metal layers 181 and 182, and contacts and vias. The layout of the conductive structures 164, 165, 166 may be rectangular. For the conductive structures 164, 165, and 166, the rectangle can have a short side along the X direction and a long side along the Y direction. The layout of the metal layers 181 and 182 may be rectangular. For the layout of the metal layers 181 and 182, the rectangle can have a short side along the Y direction and a long side along the X direction. The metal layers 181 and 182 can electrically connect to the conductive structures 164, 165, and 166 through the contacts or the vias.

The transistor 14 may include the conductive structures 167, 168, and 169, the metal layers 183 and 184, and contacts and vias. The layout of the conductive structures 167, 168, and 169 may be rectangular. For the layout of the conductive structures 167, 168, and 169, the rectangle can have a short side along the X direction and a long side along the Y direction. The layout of the metal layer 184 may be rectangular. For the layout of the metal layer 184, the rectangle can have a short side along the Y direction and a long side along the X direction. The metal layer 184 can electrically connect to the conductive structures 167, 168, and 169 through the contacts or the vias.

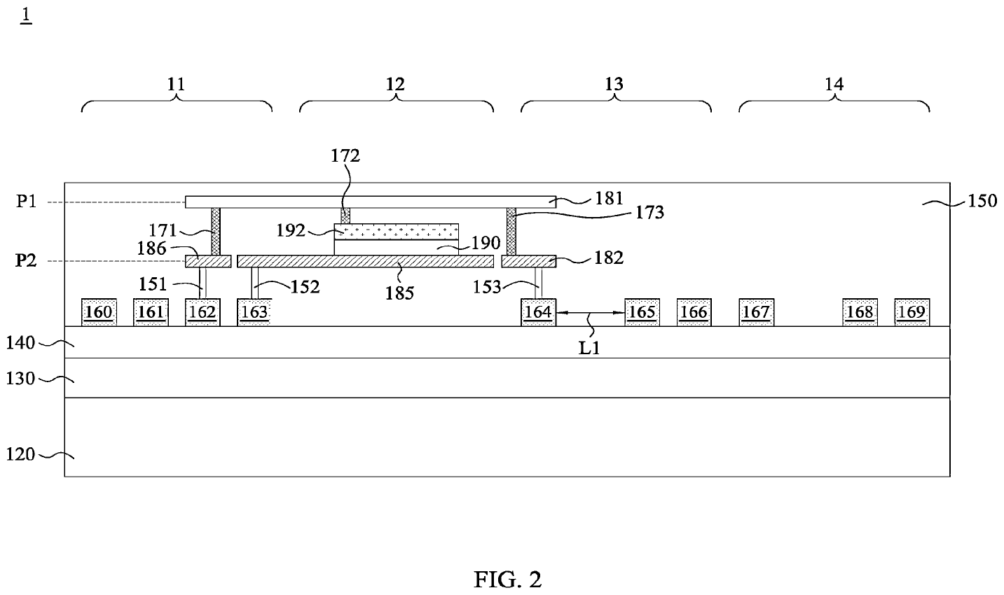

FIG. 2 is a cross-sectional view of a semiconductor device 1 along the section line A1-A2 in FIG. 1 according to some embodiments of the present disclosure.

As shown in FIG. 2, the clamping element 11, the capacitor 12, the switching element 13 and the transistor 14 of the semiconductor device 1 may be formed on the substrate 120, the nitride semiconductor layer 130 and the nitride semiconductor layer 140. The clamping element 11, the capacitor 12, the switching element 13 and the transistor 14 may be formed in or embedded within the passivation layer 150.

The substrate 120 may include, for example, but is not limited to, silicon (Si), doped silicon (doped Si), silicon carbide (SiC), germanium silicide (SiGe), gallium arsenide (GaAs), or another semiconductor material. In some embodiments, the substrate 120 may include an intrinsic semiconductor material.

In some embodiments, the substrate 120 may include a p-type semiconductor material. In some embodiments, the substrate 120 may include a silicon layer doped with boron (B). In some embodiments, the substrate 120 may include a silicon layer doped with gallium (Ga). In some embodiments, the substrate 120 may include an n-type semiconductor material. In some embodiments, the substrate 120 may include a silicon layer doped with arsenic (As). In some embodiments, the substrate 120 may include a silicon layer doped with phosphorus (P).

In addition, a buffer layer may be disposed on the substrate 120. In some embodiments, the buffer layer may include nitrides. In some embodiments, the buffer layer may include, for example, but is not limited to, aluminum nitride (AlN). In some embodiments, the buffer layer may include, for example, but is not limited to, aluminum gallium nitride (AlGaN). The buffer layer may include a multilayer structure. The buffer layer may include a superlattice layer with periodic structure of two or more materials. The buffer layer may include a single layer structure.

The nitride semiconductor layer 130 may be disposed on the substrate 120. The nitride semiconductor layer 130 may be disposed on the buffer layer. The nitride semiconductor layer 130 may include, for example, but is not limited to, group III nitride. The nitride semiconductor layer 130 may include, for example, but is not limited to, GaN. The nitride semiconductor layer 130 may include, for example, but is not limited to, AlN. The nitride semiconductor layer 130 may include, for example, but is not limited to, InN. The nitride semiconductor layer 130 may include, for example, but is not limited to, compound InₓAl_{y}Ga_{1-x-y}N, where x+y≤1. The nitride semiconductor layer 130 may include, for example, but is not limited to, compound Al_{y}Ga_{(1-y)} N, where y≤1.

The nitride semiconductor layer 140 may be disposed on the nitride semiconductor layer 130. The nitride semiconductor layer 140 may include, for example, but is not limited to, group III nitride. The nitride semiconductor layer 140 may include, for example, but is not limited to, compound Al_{y}Ga_{(1-y)} N, where y≤1. The nitride semiconductor layer 140 may include, for example, but is not limited to, GaN. The nitride semiconductor layer 140 may include, for example, but is not limited to, AlN. The nitride semiconductor layer 140 may include, for example, but is not limited to, InN. The nitride semiconductor layer 140 may include, for example, but is not limited to, compound InₓAl_{y}Ga_{1-x-y}N, where x+y≤1.

A heterojunction may be formed between the nitride semiconductor layer 140 and the nitride semiconductor layer 130. The nitride semiconductor layer 140 may have a band gap greater than a band gap of the nitride semiconductor layer 130. For example, the nitride semiconductor layer 140 may include AlGaN that may have a band gap of about 4 eV, and the nitride semiconductor layer 130 may include GaN that may have a band gap of about 3.4 eV.

In the semiconductor device 1, the nitride semiconductor layer 130 may be used as a channel layer. In the semiconductor device 1, the nitride semiconductor layer 130 may be used as a channel layer disposed on the semiconductor substrate 120. In the semiconductor device 1, the nitride semiconductor layer 140 may be used as a barrier layer. In the semiconductor device 1, the nitride semiconductor layer 140 may be used as a barrier layer disposed on the nitride semiconductor layer 130.

In the semiconductor device 1, because the band gap of the nitride semiconductor layer 130 is less than the band gap of the nitride semiconductor layer 140, two dimensional electron gas (2DEG) may be formed in the nitride semiconductor layer 130. In the semiconductor device 1, because the band gap of the nitride semiconductor layer 130 is less than the band gap of the nitride semiconductor layer 140, 2DEG may be formed in the nitride semiconductor layer 130 and the 2DEG is close to the interface of the nitride semiconductor layer 140 and the nitride semiconductor layer 130. In the semiconductor device 1, because the band gap of the nitride semiconductor layer 140 is greater than the band gap of the nitride semiconductor layer 130, 2DEG may be formed in the nitride semiconductor layer 130. In the semiconductor device 1, because the band gap of the nitride semiconductor layer 140 is greater than the band gap of the nitride semiconductor layer 130, 2DEG may be formed in the nitride semiconductor layer 130 and the 2DEG is close to the interface of the nitride semiconductor layer 140 and the nitride semiconductor layer 130.

The passivation layer 150 may be disposed on the nitride semiconductor layer 140. The passivation layer 150 may extend on the nitride semiconductor layer 140. The passivation layer 150 may include a dielectric material. The passivation layer 150 may include a non-group III-V dielectric material. The passivation layer 150 may include nitride. The passivation layer 150 may include, for example, but is not limited to, silicon nitride (Si₃N₄). The passivation layer 150 may include oxide. The passivation layer 150 may include, for example, but is not limited to, silicon oxide (SiO₂).

The conductive structures 160, 160, 161, 162, 163, 164, 165, 166, 167, 168, and 169 may be disposed on the semiconductor layer 140. The conductive structures 160 to 169 may contact the semiconductor layer 140. The conductive structures 160 to 169 may electrically connect to the semiconductor layer 130. The conductive structures 160 to 169 may electrically connect to the semiconductor layer 130 through the nitride semiconductor layer 140. The conductive structures 160 to 169 may be surrounded by the passivation layer 150. The conductive structures 160 to 169 may include a conductive material. The conductive structures 160 to 169 may include a metal. The conductive structures 160 to 169 may include, for example, but are not limited to, Al. The conductive structures 160 to 169 may include, for example, but are not limited to, Ti. The conductive structures 160 to 169 may include a metal compound. The conductive structures 160 to 169 may include, for example, but are not limited to, AlN. The conductive structures 160 to 169 may include, for example, but are not limited to, TiN.

In some embodiments, the conductive structures 160, 161, 162 and 163 may be included in the clamping element 11. The conductive structures 164, 165, and 166 may be included in the switching element 13. The conductive structures 167, 168, and 169 may be included in the transistor 14. The conductive structure 160 can electrically connect to a node Vin of the clamping element 11. The conductive structure 161 can electrically connect to a node Vout of the clamping element 11. The conductive structure 162 can electrically connect to a node Vcc of the clamping element 11. The conductive structure 163 can electrically connect to a ground node GND of the clamping element 11.

Moreover, the conductive structure 164 may be used as, for example, but is not limited to, a drain electrode of the switching element 13. The conductive structure 165 may be used as, for example, but is not limited to, a gate electrode of the switching element 13. The conductive structure 164 is spaced apart from the conductive structure 165 by a distance L1. The distance L1 may be a length between the drain electrode and the gate electrode. The conductive structure 166 may be used as, for example, but is not limited to, a source electrode of the switching element 13.

In addition, the conductive structure 167 may be used as, for example, but is not limited to, a source electrode of the transistor 14. The conductive structure 168 may be used as, for example, but is not limited to, a gate electrode of the transistor 14. The conductive structure 169 may be used as, for example, but is not limited to, a drain electrode of the transistor 14.

The metal layers 181, 182, 185, and 186 may be surrounded by the passivation layer 150. Each of the metal layers 181, 182, 185, and 186 may be isolated by the passivation layer 150. The metal layer 181 may be formed substantially in or along the plane P1. The metal layers 182, 185, and 186 may be formed substantially in or along the plane P2. The metal layers 182, 185, and 186 are coplanar. The plane P1 may be substantially parallel to the plane P2. The plane P1 may be above the plane P2. The plane P2 may be under the plane P1.

In some embodiments, the metal layer 181 may be included in the clamping element 11, the capacitor 12, and the switching element 13. The metal layer 181 may be included in the clamping element 11. The metal layer 181 may be included in the capacitor 12. The metal layer 181 may be included in the switching element 13. The metal layer 186 may be included in the clamping element 11. The metal layer 185 may be included in the clamping element 11 and the capacitor 12. The metal layer 185 may be included in the clamping element 11. The metal layer 185 may be included in the capacitor 12. The metal layer 182 may be included in the switching element 13.

The metal layers 181, 182, 185, and 186 may include a single layer of metal, metal composite, or layers of conductive materials. For example, the metal layers 181, 182, 185, and 186 may include titanium (Ti), titanium nitride (TiN), tantalum (Ta), tantalum nitride (TaN), tungsten nitride (WN), a stack thereof or a combination thereof. The metal layers 181, 182, 185, and 186 may include tungsten (W), copper (Cu), aluminum (Al), silver (Ag), an alloy thereof, or a combination thereof. The metal layers 181, 182, 185, and 186 may include at least one material selected from among a polysilicon (poly-Si), a metal silicide, a metal nitride, and a metal.

In some embodiments, the metal layer 186 can electrically connect to the conductive structure 162 through the via 151. The metal layer 185 can electrically connect to the conductive structure 163 through the via 152. The metal layer 182 can electrically connect to the conductive structure 164 through the via 153. The vias 151, 152 and 153 may include doped polysilicon (poly-Si), titanium (Ti), titanium nitride (TiN), tantalum (Ta), tantalum nitride (TaN), tungsten (W), copper (Cu), aluminum (Al) or an alloy thereof.

In some embodiments, the metal layer 181 can electrically connect to the metal layer 186 through the via 171. The metal layer 181 can electrically connect to the conductive layer 192 through the via 172. The insulating layer 190 may be formed between the conductive layer 192 and the metal layer 185. The area of the insulating layer 190 is substantially the same as that of the conductive layer 192. The conductive layer 192 and the metal layer 185 may become two electrodes of the capacitor 12. The metal layer 181 can electrically connect to the metal layer 182 through the via 173. The vias 171, 172 and 173 may include doped polysilicon (poly-Si), titanium (Ti), titanium nitride (TiN), tantalum (Ta), tantalum nitride (TaN), tungsten (W), copper (Cu), aluminum (Al) or an alloy thereof.

In some embodiments, the capacitor 12 can include the metal layer 181, the via 172, the conductive layer 192, the insulating layer 190, and the metal layer 185. The capacitor 12 may be used to store charges from the transistor 14. The capacitor 12 may be used to store electrons from the transistor 14. The capacitor 12 may be used to dissipate current from the gate of the transistor 14 during abnormalities to protect the semiconductor device 1.

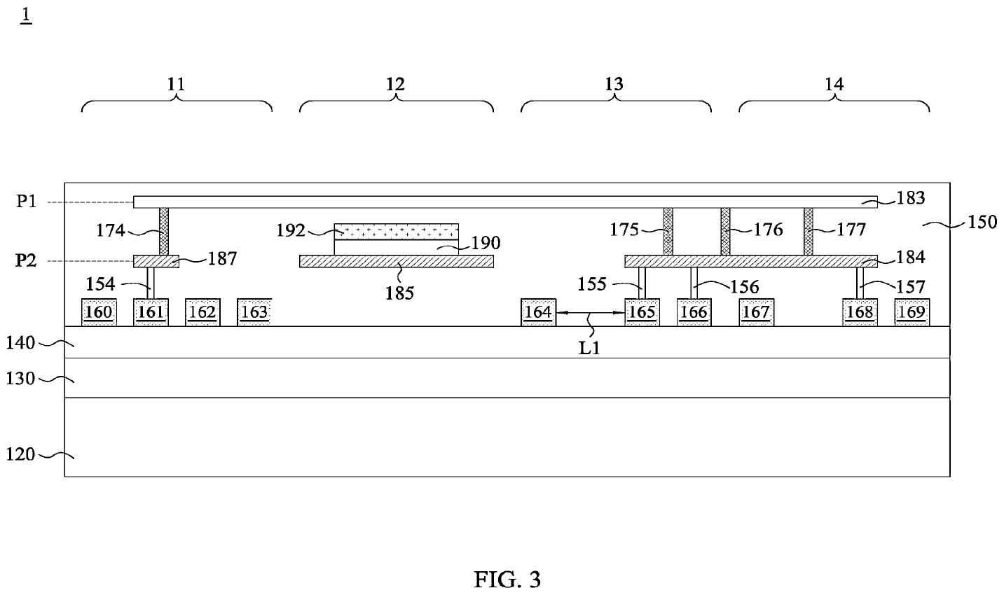

FIG. 3 is a cross-sectional view of a semiconductor device 1 along the section line B1-B2 in FIG. 1 according to some embodiments of the present disclosure.

As shown in FIG. 3, the clamping element 11, the capacitor 12, the switching element 13 and the transistor 14 of the semiconductor device 1 may be formed on the substrate 120, the nitride semiconductor layer 130, and the nitride semiconductor layer 140. The clamping element 11, the capacitor 12, the switching element 13, and the transistor 14 may be formed in or embedded within the passivation layer 150.

The clamping element 11 can include conductive structures 160, 161, 162, and 163, a via 154, a metal layer 187, a via 174, and a portion of a metal layer 183. The conductive structures 160, 161, 162, and 163 are formed or disposed on the nitride semiconductor layer 140. The conductive structures 160, 161, 162, and 163 may be in direct contact with the nitride semiconductor layer 140.

The metal layer 187 may be formed above the conductive structures 160, 161, 162 and 163. The metal layer 187 may be formed along the plane P2. The metal layer 183 may be formed above the metal layer 187. The metal layer 187 can electrically connect to the conductive structure 161 through the via 154. The metal layer 183 may be formed along the plane P1. The plane P1 may be substantially parallel to the plane P2. The metal layer 183 can electrically connect to the metal layer 187 through the via 174.

The capacitor 12 can include the insulating layer 190, the conductive layer 192, the metal layer 185 and a portion of the metal layer 183. The metal layer 183 may be formed along the plane P1. The metal layer 185 may be formed along the plane P2. The metal layer 183 may be formed above the metal layer 185. The metal layer 183 may be spaced from the metal layer 185. The metal layer 183 may be physically isolated from the metal layer 185. The insulating layer 190 may be formed on the metal layer 185. The insulating layer 190 may be in direct contact with the metal layer 185. The conductive layer 192 may be formed on the insulating layer 190. The conductive layer 192 may be in direct contact with the insulating layer 190.

The switching element 13 can include the conductive structures 164, 165, and 166, the vias 155 and 156, the vias 175 and 176, a portion of a metal layer 183, and a portion of a metal layer 184. The conductive structures 164, 165, and 166 are formed or disposed on the nitride semiconductor layer 140. The conductive structures 164, 165, and 166 may be in direct contact with the nitride semiconductor layer 140.

The metal layer 184 may be formed above the conductive structures 164, 165, and 166. The metal layer 184 may be formed along the plane P2. The metal layer 183 may be formed above the metal layer 184. The metal layer 184 can electrically connect to the conductive structure 165 through the via 155. The metal layer 184 can electrically connect to the conductive structure 166 through the via 156. The metal layer 183 may be formed along the plane P1. The plane P1 may be substantially parallel to the plane P2. The metal layer 183 can electrically connect to the metal layer 184 through the vias 175, 176, and 177.

The transistor 14 can include the conductive structures 167, 168, and 169, the via 157, the via 177, a portion of a metal layer 183, and a portion of a metal layer 184. The conductive structures 167, 168, and 169 are formed on the nitride semiconductor layer 140. The conductive structures 167, 168, and 169 may be in direct contact with the nitride semiconductor layer 140. The metal layer 184 may be formed above the conductive structures 167, 168, and 169. The metal layer 183 may be formed above the metal layer 184. The metal layer 184 can electrically connect to the conductive structure 168 through the via 157. The metal layer 183 can electrically connect to the metal layer 184 through the vias 175, 176, and 177.

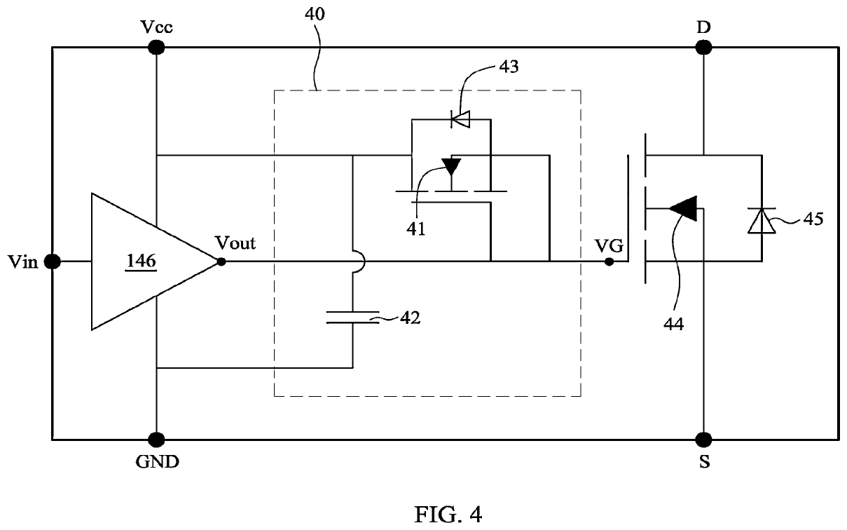

FIG. 4 is a schematic circuit diagram of a semiconductor device 4 according to some embodiments of the present disclosure. The semiconductor device 4 can include a protection circuit 40, a transistor 44, a diode 45 and a driver 146. The protection circuit 40 may be coupled between the driver 146 and the transistor 44. The driver 146 may be electrically connected the protection circuit 40. The protection circuit 40 may be electrically connected to the transistor 44.

The driver 146 can include four pins connected to the nodes Vin, Vcc, Vout, and GND. The driver 146 may be powered or biased from the node Vcc. The driver 146 can receive an input signal from the node Vin. The driver 146 can transmit an output signal to the protection circuit 40 and the transistor 44 through the node Vout. The driver 146 can transmit an output signal to the protection circuit 40 through the node Vout. The driver 146 can transmit an output signal to the transistor 44 through the node Vout. The driver 146 can electrically connect to the ground by the node GND. The driver 146 may be used to amplify the input signal for driving the transistor 44. The driver 146 may be used to rectify the input signal and generate the output signal accordingly. The driver 146 may be used to adjust the input signal and generate the output signal accordingly.

The protection circuit 40 may include a clamping element 41, a capacitor 42 and a diode 43. The capacitor 42 shown in FIG. 4 may correspond to the capacitor 12 shown in FIG. 2 and FIG. 3. The capacitor 42 may be connected between the node Vcc and the node GND. The capacitor 42 may be electrically arranged parallel to the driver 146.

The clamping element 41 may be a transistor. The clamping element 41 may be a NMOS transistor or a PMOS transistor. The clamping element 41 shown in FIG. 4 may correspond to the clamping element 11 shown in FIG. 2 and FIG. 3. The gate of the clamping element 41 may be electrically connected to the node Vout. The drain of the clamping element 41 may be electrically connected to the node Vcc. The source of the clamping element 41 may be electrically connected to the node VG. The gate of the clamping element 41 may be in connection with the source of the clamping element 41. The gate of the clamping element 41 may be in direct connection with the source of the clamping element 41. The gate of the clamping element 41 can electrically short the source of the clamping element 41. The clamping element 41 can function as a diode.

The diode 43 shown in FIG. 4 may correspond to the switching element 13 shown in FIG. 2 and FIG. 3. The diode 43 may be arranged electrically parallel to the clamping element 41. The anode of the diode 43 can electrically connect to the node VG. The anode of the diode 43 can electrically connect to the gate of the clamping element 41. The anode of the diode 43 can electrically connect to the source of the clamping element 41. The cathode of the diode 43 can electrically connect to the node Vcc. The cathode of the diode 43 can electrically connect to the drain of the clamping element 41. The cathode of the diode 43 can electrically connect to the capacitor 42.

The transistor 44 shown in FIG. 4 may correspond to the transistor 14 shown in FIG. 2 and FIG. 3. The transistor 44 may be a heterojunction bipolar transistor (HBT), a heterojunction field effect transistor (HFET), a high-electron-mobility transistor (HEMT) or a modulation-doped FET (MODFET). The gate of the transistor 44 can electrically connect to the node VG. The drain of the transistor 44 can electrically connect to the node D and the node Vcc. The source of the transistor 44 can electrically connect to the node S and the node GND. The source of the transistor 44 can electrically connect to the node S. The source of the transistor 44 can electrically connect to the node GND.

The diode 45 may be formed electrically parallel to the transistor 44. The anode of the diode 45 can electrically connect to the source of the transistor 44. The cathode of the diode 45 can electrically connect to the drain of the transistor 44. The diode 45 may be identical to the diode 43. The diode 45 may be different from the diode 43. The diode 45 may be equivalent to the transistor 44. The diode 45 may be omitted for the semiconductor device 4.

In some embodiments, the transistor 44 may be used as a high power device or a high speed device. When the voltage on the node VG is abnormally high, the protection circuit 40 may be enabled to protect the transistor 44 from damage. In some embodiments, when the voltage at the node VG exceeds a threshold voltage, the diode 43 is turned on to create a current path. The clamping element 41 may be used to disperse electrons and clamp the voltage for the transistor 44. The electrons may be dispelled or depleted through the current path from the gate of the transistor 44. The dispelled electrons may be stored or accumulated by the capacitor 42. As a result, the voltage at the node VG may be reduced by the diode 43 and the clamping element 41. The voltage at node VG of the transistor 44 may be clamped to avoid being abnormally increased and to prevent the transistor 44 from deterioration. The reliability of the semiconductor device 4 may be improved.

In some embodiments, the clamping element 41, the capacitor 42, the diode 43 and the transistor 44 may be formed or disposed on the same substrate and nitride semiconductor layers, for example, as illustrated in FIG. 2 and FIG. 3. The clamping element 41, the capacitor 42, the diode 43, and the transistor 44 may be integrated or assembled. The area of the semiconductor device 4 may be reduced due to the integration. The parasitic parameters may be low due to integration on the same substrate and nitride semiconductor layers, and the performance of the semiconductor device 4 may be enhanced for high speed operation and computing.

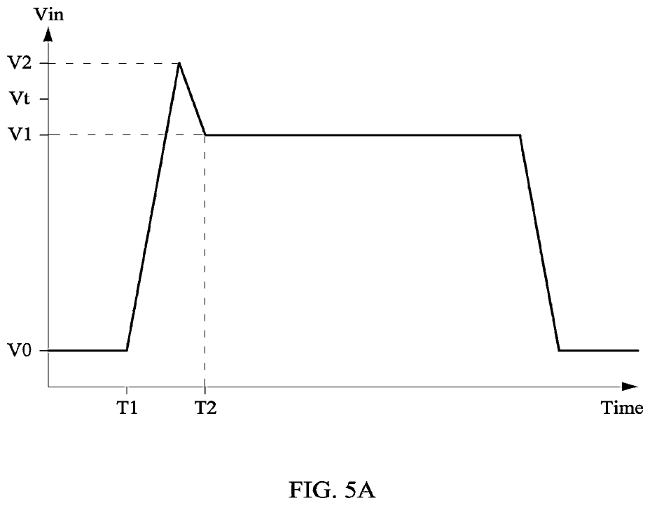

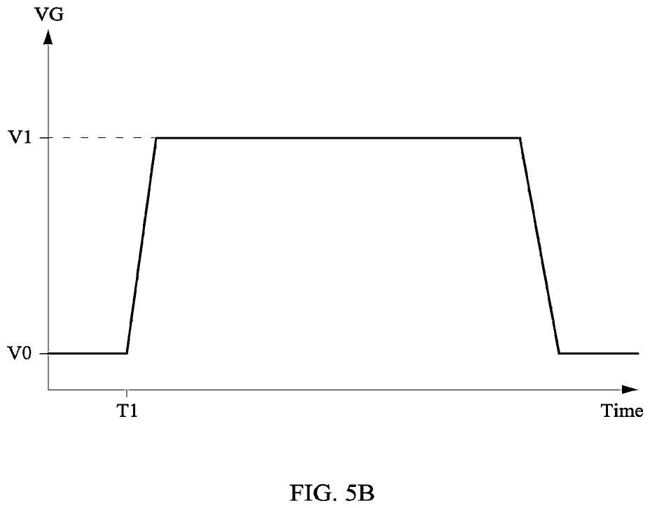

FIG. 5A is a schematic illustrating the voltage of the node Vin of the semiconductor device 4 according to some embodiments of the present disclosure. The voltage of the node Vin is V0 at time T1, and increases to V1 and V2 subsequently. The voltage on the gate of the transistor can also be increased correspondingly. In some embodiments, when the voltage of the node Vin is greater than a threshold voltage Vt, the protection circuit 40 will be enabled to deplete electrons and clamp voltages. Afterwards, the voltage of the node Vin may be reduced. As shown in FIG. 5A, the voltage of the node Vin is decreased from V2 and reaches V1 at time T2.

FIG. 5B is a schematic illustrating the voltage of the node VG of the semiconductor device 4 according to some embodiments of the present disclosure. The embodiment of FIG. 5B can correspond to the embodiment of FIG. 5A. The voltage of the node VG is V0 at time T1, and it increases to V1. Compared to the voltage at the node Vin exceeding V1 and reaching V2, the voltage at the node VG is clamped and retained at V1 due to the clamping element 41, the capacitor 42 and the diode 43 of the protection circuit 40. Therefore, the transistor 44 may be protected from damage by the impact of high voltage.

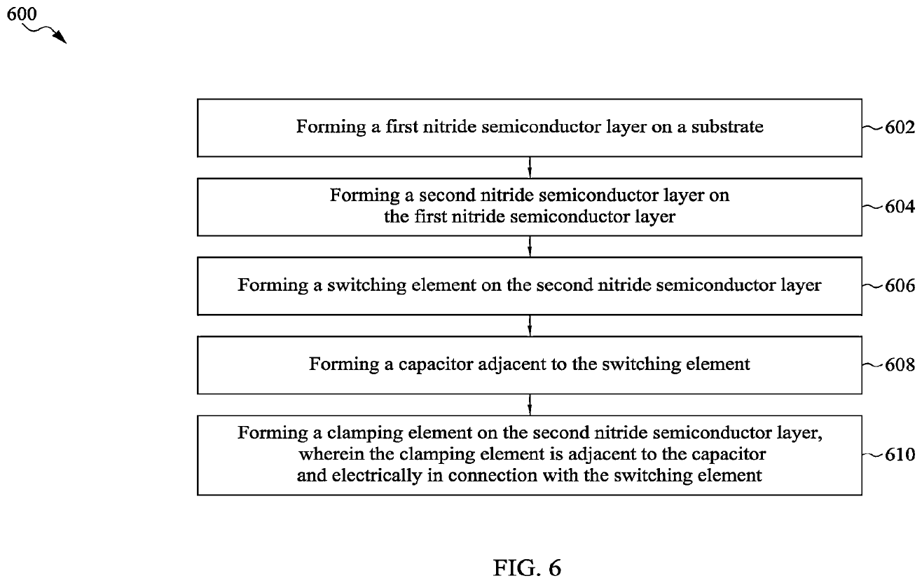

FIG. 6 is a flowchart 600 of operations in the manufacture of a semiconductor device according to some embodiments of the present disclosure. In step 602, a first nitride semiconductor layer on a substrate is formed. In step 604, a second nitride semiconductor layer is formed on the first nitride semiconductor layer. In step 606, a switching element is formed on the second nitride semiconductor layer. In step 608, a capacitor is formed adjacent to the switching element. In step 610, a clamping element is formed on the second nitride semiconductor layer. The clamping element is adjacent to the capacitor and electrically connected to the switching element.

While disclosed methods (e.g., flowchart 600) are illustrated and described as a series of acts or events, it will be appreciated that the illustrated ordering of such acts or events is not to be interpreted in a limiting sense. For example, some operations may occur in different order and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

As used herein, spatially relative terms, such as “beneath,” “below,” “lower,” “above,” “upper,” “higher.” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially.” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%,±1%, or ±0.5% of an average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

1. A semiconductor device, comprising:
a substrate;
a first nitride semiconductor layer on the substrate;
a second nitride semiconductor layer on the first nitride semiconductor layer;
a switching element on the second nitride semiconductor layer;
a capacitor adjacent to the switching element; and
a clamping element on the second nitride semiconductor layer, wherein the clamping element is adjacent to the capacitor and electrically connected to the switching element.

2. The semiconductor device according to claim 1, wherein the second nitride semiconductor layer has a band gap larger than a band gap of the first semiconductor layer.

3. The semiconductor device according to claim 1, wherein the switching element comprises a first conductive structure on the second nitride semiconductor layer, electrically connected to the capacitor and the clamping element through a first metal layer and a second metal layer.

4. The semiconductor device according to claim 3, wherein the switching element further comprises:
a second conductive structure on the second nitride semiconductor layer; and
a third conductive structure on the second nitride semiconductor layer, wherein the second conductive structure and the third conductive structure are electrically connected to the clamping element through a third metal layer and a fourth metal layer.

5. The semiconductor device according to claim 1, wherein the switching element comprises a diode.

6. The semiconductor device according to claim 4, further comprising a transistor electrically connected to the switching element, wherein the transistor comprises a source electrode, a gate electrode and a drain electrode which are disposed on the second nitride semiconductor layer.

7. The semiconductor device according to claim 6, wherein the gate electrode of the transistor is electrically connected to the switching element and the clamping element through the third metal layer and the fourth metal layer.

8. The semiconductor device according to claim 3, wherein the capacitor comprises:
a fifth metal layer on the second nitride semiconductor layer;
a conductive layer; and
an insulating layer between the fifth metal layer and the conductive layer.

9. The semiconductor device according to claim 8, wherein an area of the conductive layer is substantially equal to an area of the insulating layer, and the area of the conductive layer is smaller than an area of the fifth metal layer.

10. The semiconductor device according to claim 8, wherein the clamping element comprises a fourth conductive structure on the second nitride semiconductor layer, electrically connected to the fifth metal layer of the capacitor.

11. The semiconductor device according to claim 10, wherein the clamping element further comprises a fifth conductive structure on the second nitride semiconductor layer, electrically connected to the first metal layer through a sixth metal layer.

12. The semiconductor device according to claim 11, wherein the clamping element further comprises a sixth conductive structure on the second nitride semiconductor layer, electrically connected to the third metal layer through a seventh metal layer.

13. The semiconductor device according to claim 12, wherein the first metal layer and the third metal layer are located substantially in a first plane.

14. The semiconductor device according to claim 13, wherein the second metal layer, the fourth metal layer, the fifth metal layer, the sixth metal layer and the seventh metal layer are located substantially in a second plane, and the second plane is substantially parallel with the first plane.

15. The semiconductor device according to claim 14, wherein the insulating layer and the conductive layer of the capacitor is between the first plane and the second plane.

16. A method for manufacturing a semiconductor device, comprising:
forming a first nitride semiconductor layer on a substrate;
forming a second nitride semiconductor layer on the first nitride semiconductor layer;
forming a switching element on the second nitride semiconductor layer;
forming a capacitor adjacent to the switching element; and
forming a clamping element on the second nitride semiconductor layer, wherein the clamping element is adjacent to the capacitor and electrically connected to the switching element.

17. The method according to claim 16, wherein forming the switching element further comprises forming a first conductive structure on the second nitride semiconductor layer, electrically connected to the capacitor and the clamping element through a first metal layer and a second metal layer.

18. The method according to claim 17, wherein forming the switching element further comprises:
forming a second conductive structure on the second nitride semiconductor layer; and
forming a third conductive structure on the second nitride semiconductor layer, wherein the second conductive structure and the third conductive structure are electrically connected to the clamping element through a third metal layer and a fourth metal layer.

19. The method according to claim 16, further comprising forming a transistor adjacent to and electrically connected to the switching element, wherein the transistor comprises a source electrode, a gate electrode and a drain electrode which are formed on the second nitride semiconductor layer.

20. The method according to claim 16, wherein forming the capacitor further comprises:
forming a fifth metal layer;
forming an insulating layer formed on the fifth metal layer; and
forming a conductive layer formed on the insulating layer.

21. A semiconductor device, comprising:
a substrate;
a first nitride semiconductor layer on the substrate;
a second nitride semiconductor layer on the first nitride semiconductor layer and having a band gap greater than a band gap of the first semiconductor layer;
a transistor on the second nitride semiconductor layer; and
a protection circuit on the second nitride semiconductor layer, wherein the protection circuit is configured to dispel electrons from a gate node of the transistor when a voltage on the gate node exceeds a first threshold voltage.

22. The semiconductor device according to claim 21, wherein the protection circuit further comprises:
a switching element on the second nitride semiconductor layer;
a capacitor adjacent to the switching element; and
a clamping element on the second nitride semiconductor layer, wherein the clamping element is adjacent to the capacitor and electrically connected to the switching element.

23. The semiconductor device according to claim 22, wherein the switching element comprises:
a first conductive structure on the second nitride semiconductor layer, electrically connected to the capacitor and the clamping element through a first metal layer and a second metal layer;
a second conductive structure on the second nitride semiconductor layer; and
a third conductive structure on the second nitride semiconductor layer, wherein the second conductive structure and the third conductive structure are electrically connected to the clamping element through a third metal layer and a fourth metal layer.

24. The semiconductor device according to claim 22, wherein the capacitor comprises:
a fifth metal layer on the second nitride semiconductor layer;
a conductive layer; and
an insulating layer between the fifth metal layer and the conductive layer.

25. The semiconductor device according to claim 24, wherein an area of the conductive layer is substantially equal to an area of the insulating layer, and the area of the conductive layer is smaller than an area of the fifth metal layer.
